(19) United States
(12) Patent Application Publication
(10) Pub. No.: US 2026/0081104 A1
(43) Pub. Date: Mar. 19, 2026

(54) CHIP NAVIGATION USING VIRTUAL MAP INCLUDING SAMPLE NAVIGATION BASED ON HAND-DRAWN OR DIGITIALLY GENERATED IMAGES

(71) Applicant: FEI Company, Hillsboro, OR (US)

(72) Inventors: Adam Kucera, Brno (CZ); Dominik Ficek, Havirov (CZ); Zoltán Orémuš, Brno (CZ); Lukáš Hübner, Brno (CZ); Pavol Karlík, Brno (CZ)

(73) Assignee: FEI Company, Hillsboro, OR (US)

(21) Appl. No.: 19/092,896

(22) Filed: Mar. 27, 2025

Related U.S. Application Data
(60) Provisional application No. 63/695,776, filed on Sep. 17, 2024.

(51) Int. Cl. H01J 37/26; G06T 7/13; G06T 7/543; G06T 7/73; H01J 37/22

(52) U.S. Cl. CPC H01J 37/265; G06T 7/13; G06T 7/543; G06T 7/74; H01J 37/222; G06T 2200/24; G06T 2207/10056; G06T 2207/20101; G06T 2207/20104

(57) ABSTRACT

A computer-implemented method, comprising accessing an image of a sample, detecting one or more shapes in the image, constructing a virtual map based on the detected one or more shapes in the image and a set of virtual map construction rules, and based on the virtual map, automatically navigating to a target region of the sample to process the sample with a charged particle beam microscope. Another method includes accessing dynamically obtained shape data associated with an image of a sample, detecting one or more shapes in the image and converting the detected one or more shapes into found shape data, accessing artificial reference shape data, comparing the found shape data and the artificial reference shape data with an object matching optimization to determine an alignment between the found shape data and the artificial reference shape data, and navigating to a target region of the sample based on the alignment.

### CROSS REFERENCE TO RELATED APPLICATION

This application claims the benefit of U.S. Provisional Patent Application No. 63/695,776, filed Sep. 17, 2024, and is incorporated by reference herein.

### FIELD

The field is microscopic sample processing and automation with charged particle beam microscopes.

### BACKGROUND

Automatic charged particle beam microscopy (e.g., automated transmission electron microscopy) is a growing technology area that involves automated techniques and related systems for processing microscopic samples. Often, samples relate to cutting edge technologies, such as the development or manufacture of new, more complex microchips, or the probing and analysis of features of cryogenically maintained biological samples. However, a common difficulty in automating techniques at such a microscopic scale is the proper identification of targets and the efficiency with which identified targets can be processed. Unfortunately, current approaches suffer in both areas and can require excessive user intervention that is both costly and time-consuming. A need remains for improved apparatus and techniques that can address at least some of these drawbacks.

### SUMMARY

Disclosed examples include techniques and charged particle beam microscopes employing those techniques in which a virtual map can be constructed in an automated fashion for a portion of a sample being imaged. This construction can occur by detecting basic parametric shapes and relations in the imaged portion according to user-defined rules. The virtual map can then be used to automatically navigate the charged particle beam to selected targets of that imaged portion of the sample so that various processing steps may be performed in relation to the selected targets.

According to an aspect of the disclosed technology, a computer-implemented method includes accessing an image of a sample, detecting one or more shapes in the image, constructing a virtual map based on the detected one or more shapes in the image and a set of virtual map construction rules, and based on the virtual map, automatically navigating to a target region of the sample to process the sample with a charged particle beam microscope. In some examples, the accessing the image of the sample comprises, with the charged particle beam microscope, viewing a region of the sample. Some examples further include automatically navigating to a subsequent target region of the sample based on the virtual map to process the sample with the charged particle beam at the subsequent target region. In some examples, the constructing the virtual map comprises accessing embedded virtual map definitions. In some examples, the constructing the virtual map comprises accessing user-defined text-based virtual map generative rules. In some examples, the constructing the virtual map comprises interacting with a graphical user interface to draw shapes depicting one or more structures of interest. In some examples, the constructing the virtual map comprises interacting with a graphical user interface to select and arrange shapes depicting one or more structures of interest. Some examples further include accessing a processing recipe for processing the sample including the target region, wherein the recipe is assembled through selection of map targets from a list of predefined targets. Some examples further include accessing a processing recipe for processing the sample including the target region, wherein the recipe is assembled through selection of map targets from a virtual map representation. Some examples further include accessing a processing recipe for processing the sample including the target region, wherein the recipe is assembled through selection of map targets based on a reference image. In some examples, the selection of map targets based on a reference image comprises a selection of default target positions on the reference image. In some examples, the selection of map targets based on a reference image comprises a selection of user-selected precise positions of interest on the reference image. Some examples further include accessing a processing recipe for processing the sample including the target region, wherein the recipe is assembled by: selecting a target position in relation to a virtual map arrangement, determining a shape nearest to the selected target position based on a Euclidean distance, and storing in the recipe an offset vector between the selected target position and the determined nearest shape, wherein the automatic navigating to the target region of the sample comprises locating the determined nearest shape in the constructed virtual map and using the stored offset to navigate to the target region. In some examples, the constructing the virtual map based on the detected one or more shapes in the image and a set of virtual map construction rules comprises: edge detecting the image, detecting shapes in the edge detection results, comparing the arrangement of shapes defined by the virtual map construction rules and the arrangement of detected shapes, and selecting the alignment of the virtual map with respect to the accessed image having a highest likelihood. In some examples, the constructing the virtual map based on the detected one or more shapes in the image and a set of virtual map construction rules includes: accessing edge or shape detections associated with the accessed image and the virtual map construction rules, constructing point graphs of shapes connected through orientation and adjacency for shape detections and the virtual map defined by the virtual map construction rules, determining candidate anchors based on a maximum likelihood estimation score of detected shapes wherein candidate solutions are defined as pairings of anchor candidates with corresponding graphs, and for one or more candidate solutions, comparing its candidate graph with a corresponding virtual map graph to determine a closest match. Some examples include a charged particle beam microscope configured to process the sample according to any of the examples described herein. Some examples include a computer readable medium configured with stored processor-executable instructions for executing any of the examples described herein.

According to another aspect of the disclosed technology, a method includes accessing dynamically obtained shape data associated with an image of a sample, detecting one or more shapes in the image and converting the detected one or more shapes into found shape data, accessing artificial reference shape data, comparing the found shape data and the artificial reference shape data with an object matching optimization to determine an alignment between the found shape data and the artificial reference shape data, and navigating to a target region of the sample to process the sample with a charged particle beam microscope based on the alignment. In some examples, the artificial reference shape data are based on source data comprising any of: hand-drawn, digitally drawn, or algorithmically extracted images that are segmented with shapes extracted, CAD and/or GDS files that are analyzed with shapes extracted; and/or a text-based list. Some examples include a charged particle beam microscope configured to process the sample according to any of the examples described herein.

The foregoing and other objects, features, and advantages of the disclosed technology will become more apparent from the following detailed description, which proceeds with reference to the accompanying figures.

### BRIEF DESCRIPTION OF THE DRAWINGS

FIG. 1 is a flowchart of an automated processing method according to various disclosed examples.

FIG. 2 is a flowchart of examples of defining virtual maps that can be used in charged particle beam processing.

FIG. 3 is a flowchart of examples of assembling processing recipes that can be used in charged particle beam processing.

FIG. 4 is a flowchart of an example constructions of a virtual map.

FIG. 5 is a flowchart of a selected example of constructing a virtual map.

FIG. 6 is a flowchart of an example method of navigating to and processing a location of a sample with a charged particle beam microscope.

FIG. 7 is a schematic of an example of mapping an image to a virtual map.

FIG. 8 is a flowchart of an example method of sample navigation using input reference image data.

FIG. 9 is a flowchart of various examples for obtaining artificial reference image data.

FIG. 10 is a flowchart of an example shape-finding method.

FIG. 11 is a flowchart of an example N-M matching method.

FIG. 12 is a flowchart of another example N-M matching method.

FIG. 13 is a schematic of a generalized example of a suitable computing environment in which the described innovations may be implemented.

FIG. 14 is an example system that includes a charged particle beam microscope and/or optical microscope.

### DETAILED DESCRIPTION

Automation in microscopy can involve navigation of a targeted beam to various locations on microscopic samples, such as semiconductor chips. By way of example, this can allow a user to automatically prepare lamellae samples from specific locations on the larger sample for further analysis or processing, such as with an electron beam or ion beam, in a transmission electron microscope (TEM), focused-ion beam (FIB), deposition tool, or other instrument. Processing can entail imaging, milling, lift-out, welding, etc., as well as combinations. For many applications, a highly precise navigation on the chip or other sample is needed in order to process the specific regions of interest, such as through beam milling to produce sample lamellae. This typically involves active imaging of the sample so that the acquired images can be used as part of the navigation process. For example, many current solutions use reference images of the sample and compare dynamically acquired images to these reference images, commonly referred to as ‘tempate-matching.’ An algorithm can then find a location on the sample which best matches a reference template image so that processing can commence at the found location. This matching can be done using various computer vision methods, from simple cross-correlation to neural network solutions.

However, there are numerous drawbacks to these current approaches. One significant problem stems from the large number of automation recipes that must be stored to carry out processing of various samples. In particular, it can be time-consuming to obtain reference images and they often require substantial storage capacity. Furthermore, the algorithmic processing requirements for making comparisons can be processor-intensive. A further complication is that reference image comparison can experiences high failure rates on periodic samples as the target appearance may not be specific enough to result in a match. In order to reduce the number of recipes, template images are often shared between chip locations, manufacturing steps, and designs. But, this can further decrease robustness of the template matching approaches, due to an increased appearance mismatch.

As will be discussed further below, disclosed examples can remove the burden of creating and maintaining extensive, storage-intensive libraries of template images for various chip samples through the building of a virtual map using basic shapes and/or rules rather than relying on a particular appearance. Such approaches can reduce failure rates associated with template matching techniques and can reduce errors associated with periodicity of the chip samples. Disclosed examples can overcome some of the challenge of navigating based on the recognition that the existing template matching approaches, which rely on direct or trained image comparison, do so in a largely uninformed manner with respect to the scene being imaged during navigation.

Thus, in many examples, disclosed approaches can replicate, in some respects, certain characteristics of a manual workflow of a human operator. For example, even though a manual workflow is much slower, there is a tendency for an operator to focus on certain features, such as key structures and shapes that are shown through the field of view of the microscope. This focus can allow a human operator, who overall may operate much slower than an automated process, to navigate relatively quickly even in view of their human-based restrictions, and with a notably higher accuracy rate for locating targets. The human operator is capable visualizing the scene and can distinguish various large-scale features rapidly and can discriminate against and not be misled by certain other features, like contamination, with relative ease. This capability can allow the extension of such template recognition to different samples, layouts, and processes where is a basic commonality, e.g., with respect to physical proportions, even as the appearance and other characteristics of the different samples may diverge significantly. By contrast, existing template matching algorithms tend to be confused by the variation in appearance and therefore experience a decreased success rate of navigation.

The periodicity of sample features can be particularly problematic in automated microscope processing because many locations can visually resemble a desired target and yet a more precise understanding of the scene can be required to select a correct location. For example, with current approaches, a variation in appearance from sample to sample can require a user to prepare and acquire a reference image for each type of sample, including at each of several manufacturing steps, in order to obtain reasonable reliability in navigation. At the same time, the user may prefer to reuse processing templates as much as possible. However, with existing approaches the reuse of templates for different manufacturing steps results in decreased performance as there is a concomitant decrease in reliability of navigation.

Furthermore, existing approaches lack the ability to recognize sample features, whether on the same sample or on different samples, that may have various different various physical dimensions but otherwise share one or more common attributes, such as proportional relationships. One example is a rectangular array that is proportionately larger or smaller. More generally, different chip samples can have a significant variation in shape size, etc., but can have a similarity with respect to scale, array structure, spacing, and/or proportion, etc. Where some characteristics are invariant between different samples, existing approaches are unable to recognize the commonality, and so even with the commonality new templates are typically required. Again, preparing and storing additional templates can be onerous for a user. The ability to recognize such an invariance can be beneficial as it could allow for the use of a single template among numerous different samples that share some basic characteristics.

As discussed above, disclosed techniques and apparatus can, in some respects, algorithmically mimic human operator decisions made where the operator has higher level knowledge of the scene being viewed, e.g., by knowing what features in the field of view to seek out such as shapes and/or patterns, and what is not important such as contamination or unique structures that can be ignored. For example, the operator can have knowledge of certain important features of the chip layout in order to properly locate the desired target. However, this general knowledge approach can be extended to numerous types of microscope samples and manufacturing processes that involve automated microscopy, provided relevant features can be described in terms of geometrical shapes and their respective relations by which they compose the patterns that are specific to layout characteristics of the sample.

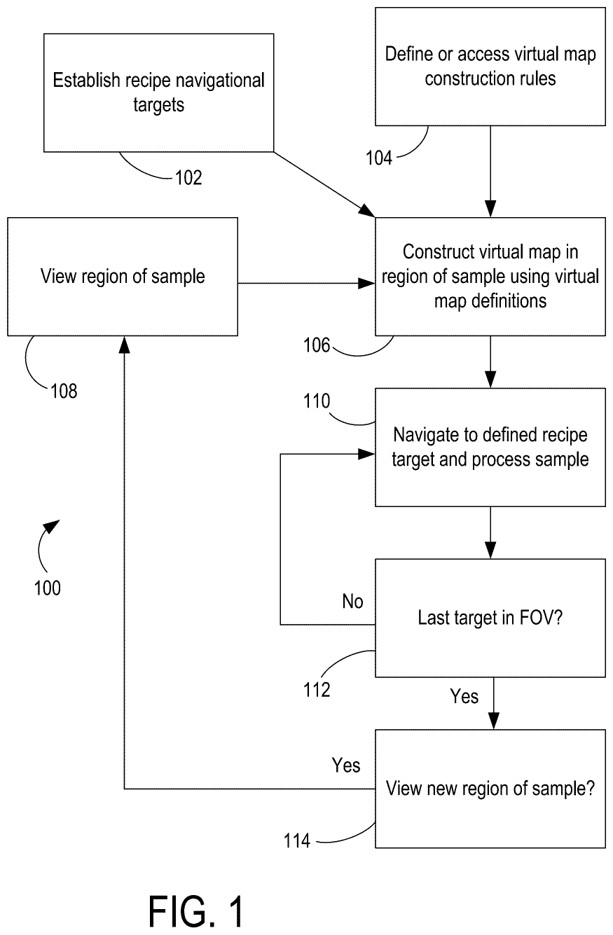

FIG. 1 is an example method 100 that can be used in automated processing of microscopic samples, including for navigation on the sample to features of interest for processing. Prior to an automated operation, a recipe can be created that includes various steps, rules, and parameters that can guide automated processing. For example, recipe creation can involve selecting beam processing characteristics, including but not limited to electron beam or ion beam intensities, focus changes, scan pathing, pulse timing and beam duration, spot size, beam sequencing, stage movements, beam repetitions, etc. Navigation commands associated with selecting and targeting various features of interest on the sample to be processed also can be included as a part of recipes or in connection with recipe selection for automated processing. For example, at 102, recipe navigational targets for automated processing can be established. As part of the automated processing of the sample, at 104, virtual map constructions rules can be defined by a user and/or accessed from memory, e.g., as being referenced to or part of a selected recipe. During processing of a sample, the virtual map construction rules can be used dynamically, at 106, to construct a virtual map using the virtual map definitions defined/accessed at 104 and a region of the sample being processed that is being viewed at 108. The virtual map constructions rules can be of a more general character than existing processor and memory intensive template matching approaches and therefore can supplement or more preferably form a basis for replacing these navigational tools.

For example, a user can have a sample arranged in an electron or ion beam chamber, such as by having the sample be coupled to a movement stage. The sample can be positioned in the field of view of the charged particle beam and can be adjusted by the user manually or automatically to view a selected region of the sample in which features of interest may be found. In response to viewing the region of the sample at 108, the virtual map can be constructed at 106. Construction can include analyzing the image of the viewed region for structures of interest that correspond to the construction rules. These structures of interest can include simple geometric shapes, which can be composed together into patterns that are specific to the type of sample, such as by being specific chip layout or a family of chip layouts. Such patterns can be described in terms of precise definition, such as a set of specifically positioned circles, rectangles, or other shapes, or in terms of generative rules, such as an array of rectangles with a predetermined spacing. The analysis can use various techniques to identify the shapes and/or pattern, such as various edge detection techniques to locate the edges of basic shapes and/or patterns, and a probability function like maximum-likelihood estimation (MLE) to determine a match for specific shapes. Virtual maps can then be aligned to the viewed region by comparing the virtual map arrangement defined by the construction rules to the arrangement of found shapes.

The virtual map can then be used as an overlay in the field of view of the viewed region for navigation to recipe navigational targets at 102. In some examples, the virtual map can be overlayed in the image of the field of view similar to a reticle, or more typically the virtual map can be a stored mapping to guide automated processing to the desired navigational targets. For example, at 110, with the virtual map constructed, the view and/or charged particle beam can be navigated to one of the defined recipe targets and the sample can be processed (imaged, milled, etc.) in relation to the defined recipe target (which can be at the targeted location, offset from the location, pathed in relation to the targeted location, etc.). Multiple targets can then be navigated to and processed in relation to the constructed virtual map. For example, at 112, if another target on the virtual map is to be processed, the process of navigation to the next location and beam processing of the new location can be repeated at 110. If there are no more targets in the current view, at 114, the automated process can determine whether another region of the sample is to be viewed for processing. The process of processing other regions and targets on the sample can proceed by viewing another region at 108, e.g., through manual or automated adjustment.

By using the virtual map constructed at 106 in automated microscope processes like AutoTEM, navigation accuracy can be improved. The virtual map can also improve time-to-recipe for automatic semiconductor chip analysis. For example, in automatic chip sample analysis in TEMs, lamellae from precise locations on the chip (selected by the user) require extraction. This can be performed using small dual-beam and large dual-beam (SDB/LDB) for navigation, milling, lift-out, and welding of the lamella onto separate ‘fingertip’ substrates inserted into the TEM. In a typical manual workflow, a human operator navigates on the sample by imaging it with the charged particle beam, which is typically an electron beam but could be an ion beam in some examples. The operator then uses prominent structures that are visible to effectively navigate to certain target locations on the chip, while ignoring unimportant details and possible contamination. These structures of interest can correspond to various prominent features of the chip layout, such as semiconductor cell mats, NAND cells, etc., and can be described in terms of simple geometric shapes. Disclosed examples like example method 100 can leverage these basic geometries to navigate by defining and using a virtual map, such as the virtual map constructed at 106.

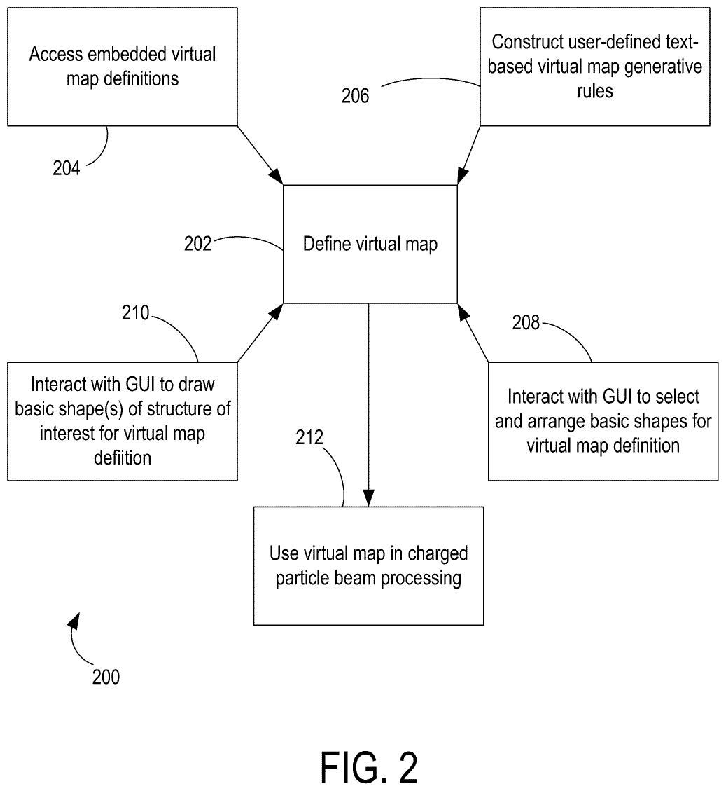

FIG. 2 illustrates various examples 200 that can be used individually or in combination to define a virtual map 202, e.g., for defining or accessing the virtual map construction rules at 104 of example 100, as well as with other examples disclosed herein. In many examples, the user can enjoy a streamlined process at 204 by which the virtual definitions are embedded, e.g., hardcoded into the application or recipe that is used during the automation process and the virtual map definitions are accessed during the automation process. In some of such examples, the user can be provided with a set of recipe targets to select from so that the navigation portion of the automated microscopy process can be customizable to a certain extent. In some examples, at 206, a text-based or other prompt can be provided to allow a user to create user-defined text-based virtual map generative rules that can summarize the basic shapes and construction of the virtual map, e.g., an M×N array with selected shapes and spacings. In additional examples, at 208, interface code can be provided so that a user can interact with a graphic user interface (GUI) to select basic shapes and arrange them in a pattern. The virtual map then can be defined at 202 using the user-arranged assemblage of basic shapes, such as the spaced relationship of different shapes, lines, etc., which can be scalable. In further examples, at 210, interface code can be provided so that a user can interact with a GUI to draw basic shapes and arrange them in a pattern that can then be used as a basis for a virtual map. The examples 200 are not exhaustive and it will be appreciated that virtual maps can be defined in other ways. At 212, the virtual map can then be used in charged particle beam processing, e.g., in navigating to selected targets of a sample.

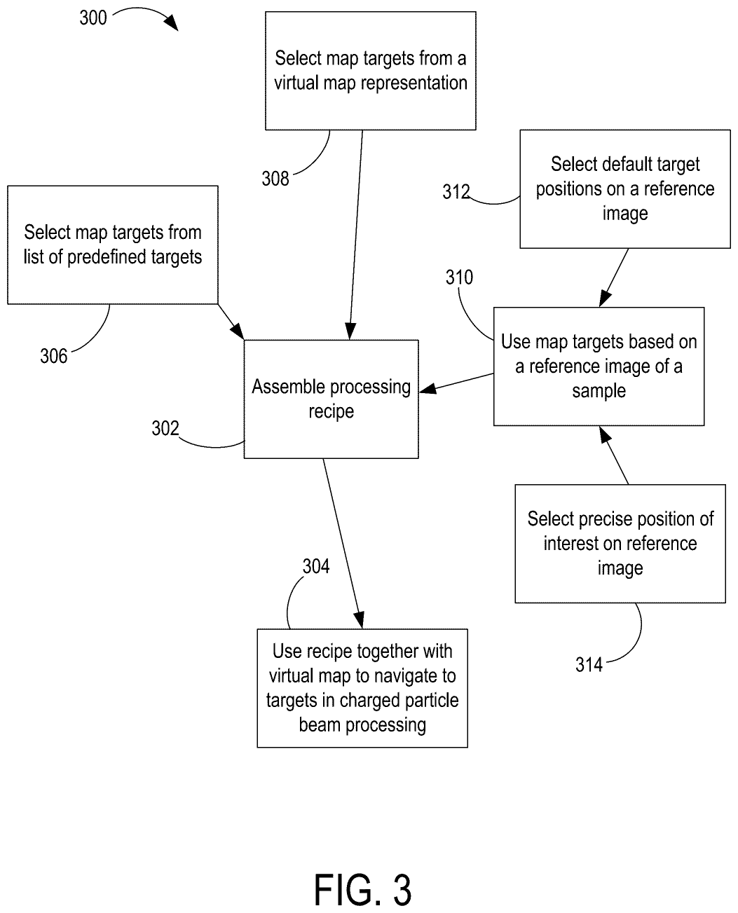

FIG. 3 illustrates various examples 300 that can be used to select navigational targets in the assembling of a processing recipe, at 302. The examples 300 can correspond to approaches used to establish recipe navigational targets at 102 of example 100, as well as other examples disclosed herein. Once established, the processing recipe can be used together with a virtual map, at 304, to navigate to targets on a sample during charged particle beam processing of the sample. In some examples, at 306, the recipe targets can be selected from a set of predefined targets, e.g., as a drop-down selection from a GUI. In some examples, map targets can be selected, at 308, from a virtual map representation displayed to the user, e.g., with selection facilitated with a pointing device or a touch sensitive screen. In some instances, the virtual map representation can be selected from one of a plurality of stored virtual maps. The selection can be for specific predefined targets, such as specific shapes, as well as specific positions relative to shapes on the virtual map representation.

In some examples, at 310, map targets can be selected based on a reference image of a sample. This can be achieved in various ways, such as by selecting default or pre-determined target positions on a reference image, at 312. Such default positions can be defined using various disclosed techniques used to construct virtual maps of a viewed region of a sample. For example, the reference image can be analyzed for structures of interest that correspond to the virtual map definitional rules. By way of example, for a virtual map 9×9 array of rectangles with a selected ratio between width and spacing in the width direction and a selected ratio of height and spacing in the height direction. The reference image can be processed through edge detection routine to identify candidates for the identify the 9×9 array and an MLE routine can be used to determine the most likely match. Once found, the default positions can be assigned based on the mapping and correspond to navigational targets for the assembled recipe. In further examples, at 314, a user can select with a GUI a specific position of interest on the reference image, e.g., using a pointing device or a touch sensitive screen. The selected position can be assigned based on the mapping and correspond to separate or additional navigational targets for the assembled recipe. In some examples, the reference image can be an artificial reference image, e.g., a hand-drawn, digitally constructed, CAD file, etc.

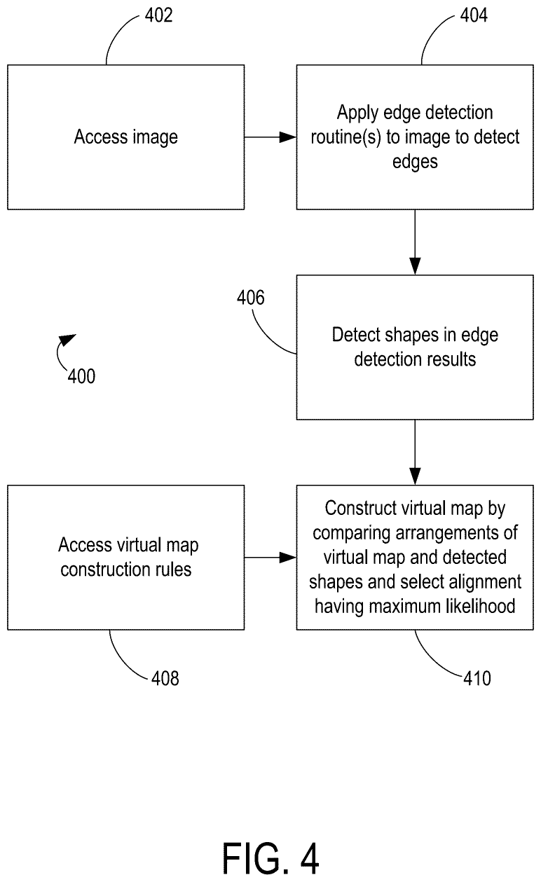

FIG. 4 shows an example method 400 of constructing a virtual map based on an image, e.g., based on an image viewed at 108 of example method 100 or based on a reference image used at 310 of examples 300 in the assembly of a processing recipe. Such construction can be used in or in connection with other examples disclosed herein as well. At 402, an image can be accessed. This can correspond to an image that is stored in memory, which can be a reference image that is not of a sample to be processed but of a different but similarly designed sample or object. In further examples, the accessed image can correspond to an image of a sample that is actively being viewed for processing, e.g., with a charged particle beam microscope.

At 404, an edge detection routine is applied to the image and, at 406, edges and shapes in the image are detected. Various edge detection techniques can be applied as well understood by those with skill in the art, including the Canny algorithm, Sobel operator, Hough transform, neural networks, etc. In a particular example involving DRAM samples, cell MATs which can be composed of rectangles are detected by first estimating an image intensity gradient using the Sobel operator. Horizontal edges are detected by analyzing a horizontal proximity of each pixel. If a gradient is approximately aligned with the Y-axis for enough nearby pixels, the central pixel is considered a horizontal edge. An analogous procedure is done for vertical edges. This gradient can be referred to as orientation coherence, which can increase detection recall for low contrast images (which can necessarily occur in samples from certain manufacturing steps). If an image has high contrast, a standard procedure of gradient magnitude thresholding can be performed. Automatic physical size inference can be done by selecting the peak in the histogram of the run-length encoding of the edge mask, row-major order for the rectangle width and column-major order for the rectangle height. Where a rectangle size is provided in advance, this selection of a peak can be skipped. Rectangle detection can be performed on the edge mask by a Hough transform formulated for a rectangle shape with known size, searching over a position parameter space (X and Y). Box filters can be used in efficient implementations.

Constructing a virtual map, at 410, can be done by using the shapes detected in the edge mask at 406 and the virtual map construction rules which can be accessed at 408. To construct the virtual map, the arrangement of the virtual map defined by the construction rules can be compared against the arrangement of detected shapes. The alignment between the two having the highest likelihood using a maximum likelihood estimation (MLE) technique can correspond to the virtual map that is selected to be associated with or as an overlay for the image. Various pattern-matching techniques can be used to perform the comparison, such as MLE graph matching, fuzzy regular expression matching, etc. In some examples, detected shapes can correspond to anchor positions for comparing the basic arrangements of the virtual map with the basic arrangement of the detected shapes. The arrangement of detected shapes can be compared with the virtual map at each anchor positions to determine a most likely match. The most likely match can then correspond to the positioning of the virtual map with respect to the image accessed at 402.

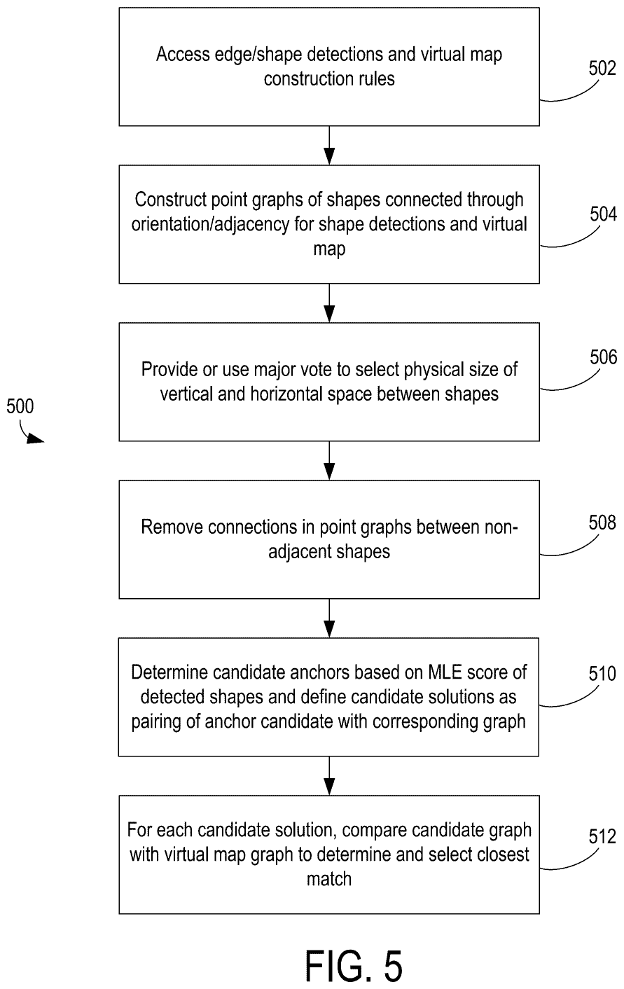

FIG. 5 is a particular example of a method 500 of constructing a virtual map that can be used for various charged particle beam microscope samples, such as DRAM samples. The virtual map construction of method 500 can be used in various examples disclosed herein, such as with example methods 100, 200, 300, 400 and subsequent examples. In some examples, the virtual map can be defined as a cartesian grid of rectangles, such as an evenly spaced two-dimensional array. In further examples, the virtual map can be multiple of such grids. At 502, edge/shape detections and virtual map constructions rules can be accessed, as stored in a memory or dynamically. For DRAM samples, the detected shapes can correspond to a set of rectangle detections. Because samples can be damaged, contain contamination, errors in their fabrication can occur (e.g., missing shapes where shapes are expected to occur), images can have poor contrast, detections may include false positives, or a misaligned virtual map can mis-target regions of interest, robust comparisons can be beneficial. In some examples, at 504, point graphs of shapes connected through orientation and adjacency can be constructed for the detected shapes and for the shape arrangement corresponding to the virtual map. For example, rectangles aligned in the vertical or horizontal direction can be connected. At 506, a major vote can be used to select the physical size of vertical and horizontal space between the rectangles, e.g., where it is not provided at 502 or otherwise. Majority vote includes a set of decision-making techniques, for example in the present case, similar physical spaces can be clustered together and the largest cluster can be selected as the correct one. Physical space can then selected as an average value of that cluster. Connections between shapes (e.g., rectangles) that are not directly adjacent (e.g., because there is another rectangle between them) can be removed at 508.

At 510, candidate anchors can be determined and selected based on a previous or currently determined MLE score for the detected shapes. For example, detected rectangles that are most likely to correspond to an expected rectangle structure, such as that obtained from a Hough transform at 406 in example method 400, can be selected as candidate anchors. Each anchor together with the mentioned graph structure now defines a candidate solution (grid). At 512, by iterating over all of the anchors, the one with the highest number of other rectangles that are consistent with the candidate solution can be selected as the correct position for the virtual map. For example, rectangles conforming to that solution, or the ones that contradict it, can be removed and the procedure is repeated until there are no more candidate solutions. Solutions that do not have enough rectangles, e.g., at least 2×2 grid in a specific example, can be discarded. In general, virtual maps can be defined using anchor-based approaches, though these approaches can be modified in various based on the complexity of the arrangements, shapes, and/or patterns being mapped. Each shape detection can define a set of possible virtual maps. For example, with a set of ten circles in a hexagonal grid, this can lead to circle-to-circle matching, from which the best match can be selected.

As discussed above, in many applications, a constructed virtual map can be used for navigating to targets on a sample to be processed with a charged particle beam. In many instances, the targeted locations can be predefined relative to the virtual map, such as by targeting a top-left corner of a selected rectangle within a grid. This can be achieved through a pattern match with respect to symbols encoding or associated with the virtual map, similar to how regular expressions are matched in a text. For example, depending on the virtual map definition, this can include basic sequential matching, or graph matching. In a specific example involving DRAM samples, a cartesian grid may be used, which allows a match to be found through two separate sequential matchings (row-wise and column-wise).

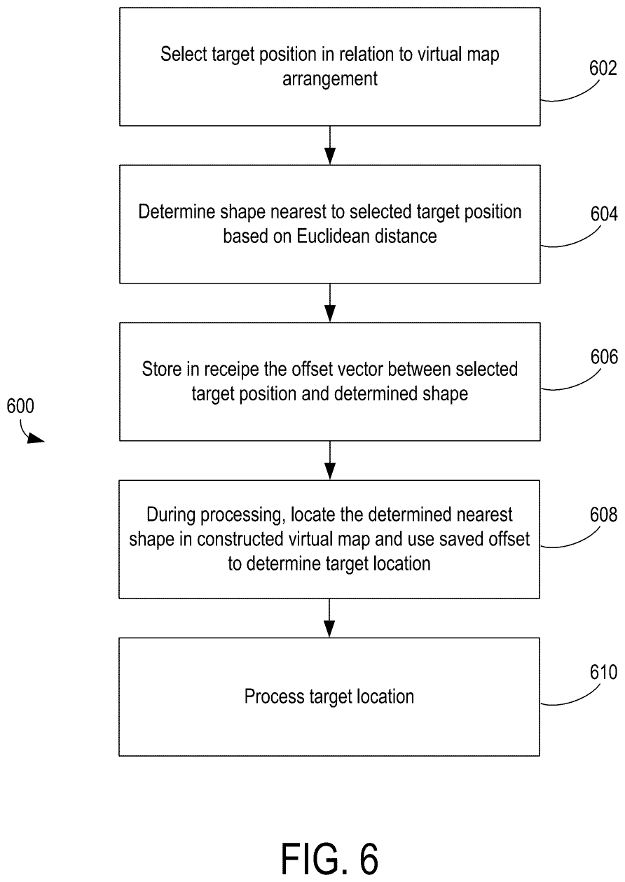

FIG. 6 shows a specific navigation example 600 in which at 602 a user selects a target position for navigating in relation to a virtual map arrangement. In many examples, this can be done offline when preparing a recipe. The example 600, can correspond to specific approach in which map targets are selected from a virtual representation at 308 of examples 300, or navigation at 110 of example method 100, as well as part of or together with examples 200, 400, 500, or other steps of examples 100, 300. At 604, the processor can determine the shape that is nearest to the selected target position based on a shortest Euclidean distance, e.g., to a shape centroid or default grid position associated with the shape. At 606, an offset vector between the selected target position on the determined shape can be stored in memory, e.g., as part of a navigation portion of a recipe file. At 608, during processing of a sample, a virtual map is often constructed in relation to a viewed region of a sample. The nearest shape determined at 604 can be found in the constructed virtual map and the stored offset can then be used to determine the target location to which the charged particle beam can be navigated.

At 610, the targeted location can then be processed with the charged particle beam. In many examples, the constructed virtual map can be scaled during shape matching and construction, such as where the targeted structures have a different scale than baseline construction rules (e.g., due to variation between chip samples, image zoom, etc.). For invariance adjustments based on variations in physical scale, offsets can also be scaled, e.g., based on the physical scale adjustment inferred in the shape detection step. In some examples, where the virtual map is a finite object with well-defined geometrical center position, this center position can be used as a reference for the offset vector as well.

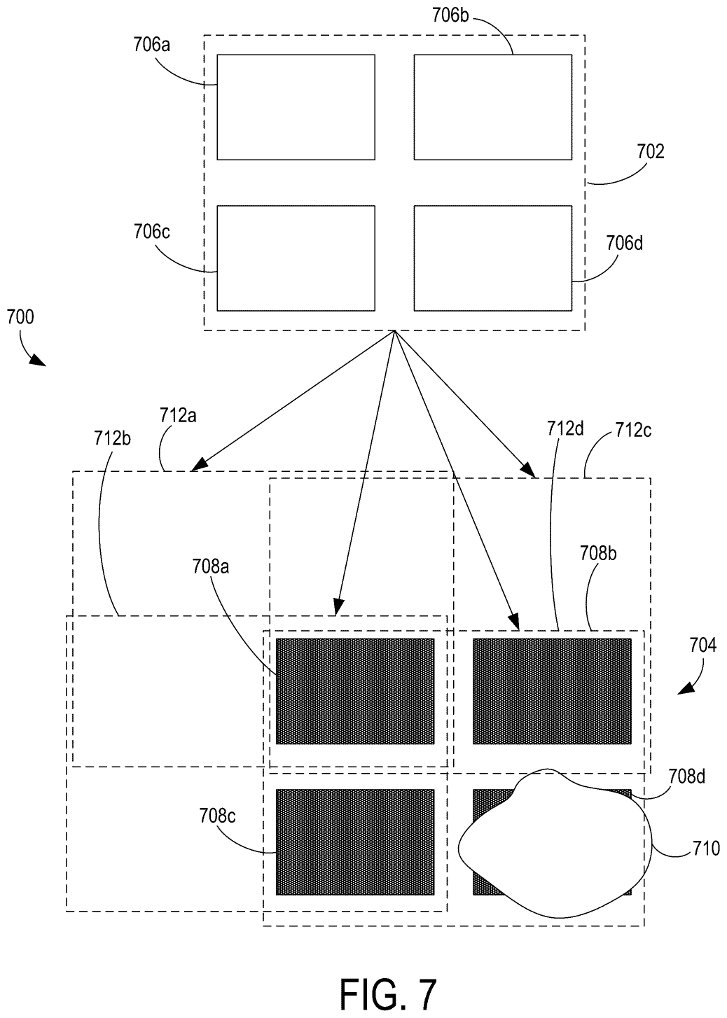

FIG. 7 is a mapping example 700 in which virtual map 702 is mapped to an acquired image 704. The virtual map 702 can be a schematic representation of an arrangement of shapes, such as four rectangles 706a-706d. The acquired image 704 can include an arrangement of shapes 708a-708d, with some aberration, occlusion, contamination or other differences with respect to the virtual map 702. As shown, contamination 710 obscures rectangular structure 708d. During a comparison matching, the virtual map 702 with its shapes 706a-706d can be compared against the acquired image 704. For example, graph characteristics of the virtual map 702 can be compared to different positions in the acquired (real) image 704, such as corresponding to positions 712a-712d. Even with the contamination 710 obscuring the rectangle 708d, the best match of the compared graphs can correspond to the correct position 712d.

### Additional Examples Using Artificial Reference Data

In many situations, it can be desirable to have a robust set of options for the types of input reference image data that can be used to create virtual maps and/or provide a basis for finding similar data in an image of interest (which can referred to as a “real” image). As discussed above, it can be difficult to provide automated navigation for sample processing because current approaches rely on image-to-image template matching. These approaches require the creation and storage of numerous reference images which can significantly increase the time to recipe. In accordance with various examples herein, artificial data that describes the sample and that can be readily available can be used to address this. Examples can include the use of available CAD data. Furthermore, artificial data can come from numerous unexpected sources, and need not be as precise as formal CAD data. For example, it has been found that crude, hand-drawn or digitally drawn images of an arrangement of rectangles can be used. That is, even with the imprecision of the crude or somewhat imprecise reference image data, because of the basic characteristics of the shapes, including spatial relationships and sizes, it is possible to use such data as a basis for navigation. Thus, in an unorthodox example, a user can draw a few rectangles on a napkin or whiteboard, snap a picture of the drawing, deliver it to a microscope, and the microscope can navigate to and find matching locations on a sample based on the hand-drawn, artificial reference data. In more general examples, a user can provide artificial image reference data in various forms to the system, the system collected an image using a microscope (e.g., SEM, FIB, Optical) and analyzed, and a matching of the structures coming from the artificial reference data and the analyzed image is performed, and based on the match a region of interest can be located and navigated to. In some examples, for more precise artificial data, matched locations can be compared to determine aberrations in the collected image of the sample, either optical (distortion, magnification, etc.) or error in the manufacture of the sample or deviation from design specifications.

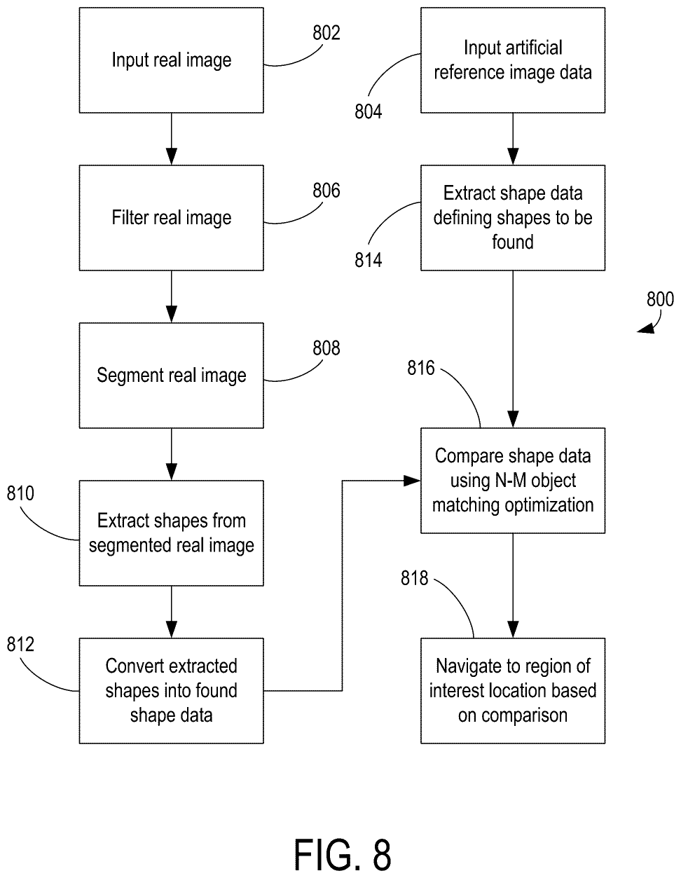

FIG. 8 shows an example method 800 of sample navigation using an artificial reference image data. By way of example, example method 800 form part of or be used in other examples disclosed herein, including but not limited to method examples 100, 200, 300, 400, 500, 600. In a processing workflow navigation can be guided by schematic images of a sample being viewed and processed. The schematic images often having varying degrees of accuracy and only provide an operator with basic guidance of what structure to be searching for in a microscopic object, such as memory circuits. As discussed above, existing automated methods typically rely on template-matching approaches that compare a field of view to reference images. Often, numerous specific reference images are required which increases the time and workflow burden in the preparation of recipes while also preventing the scalability of the recipe. Further, the reference images often have minor differences or other mismatching characteristics in relation to the viewed sample, like contamination, scale, or new, different, or omitted structures, etc., which decrease match likelihood and undermine navigational capability. By using feature matching on artificial reference image data and viewed images, and then performing an object matching routine between them, sample navigation can be streamlined for a variety of applications.

Example method 800 includes a real image 802 and an artificial reference image data 804 as inputs. The image 802 can correspond to an image of a sample that is being viewed or processed, e.g., with a scanning electron microscope (SEM), focused-ion beam (FIB), optical microscope, or other imaging device. In some examples, the image 802 can be filtered or artificial in some way as well. The artificial reference image data 804 can come from various sources, such as hand-drawn, digitally drawn, or algorithmically extracted from GDS/CAD data. For the input image 802, the image content can be filtered at 806, segmented at 808, and shapes extracted at 810 to produce data describing an arrangement of found shapes 812. For example, the found shape data can include a list of shapes, spatial relationships between shapes (e.g., grid-based information), etc. In some examples, this data can be in a graph form describing vertex-edge relations between shapes in a suitable coordinate system (e.g., Cartesian, hexagonal, polar, etc.). In many examples, these steps can be performed dynamically as a sample is being processed, e.g., during search and navigation for regions of interest for processing.

Before or during processing, the artificial reference image data 804 can be analyzed or converted (if not already in a suitable form) at 814 to shape data describing one or more shapes to be found. The shape data can be in a similar format as the found shape data at 814, such as by including a list of shapes, spatial relationships between shapes (e.g., grid-based information), etc. In some examples, this data can be in a graph form describing vertex-edge relations between shapes in a suitable coordinate system (e.g., Cartesian, hexagonal, polar, etc.). At 816, the two sets of shape data can be compared to determine a match likelihood, e.g., by using an N-M object matching optimization. This can produce an estimate of an alignment between the two sets of shape data. N-M object matching includes approaches that find a matching set of objects N among a set of objects M where M is typically greater than N. This alignment can then be used for navigation purposes, at 818, e.g., to guide a charged particle beam to selected regions of interest in the input image 802, which can be identified relative to the shapes and features of the artificial reference image data. As with other disclosed examples, affine adjustments such as scale can be made during the aligning and shape matching process so that the artificial reference image data can be robustly used in a scale invariant way. Thus, rather than using processor-intensive image processing, a less processor-intensive object matching optimization can be performed. Furthermore, this can be done for various types of artificial input image data, allowing a user a robust assortment of options to assist with navigating samples.

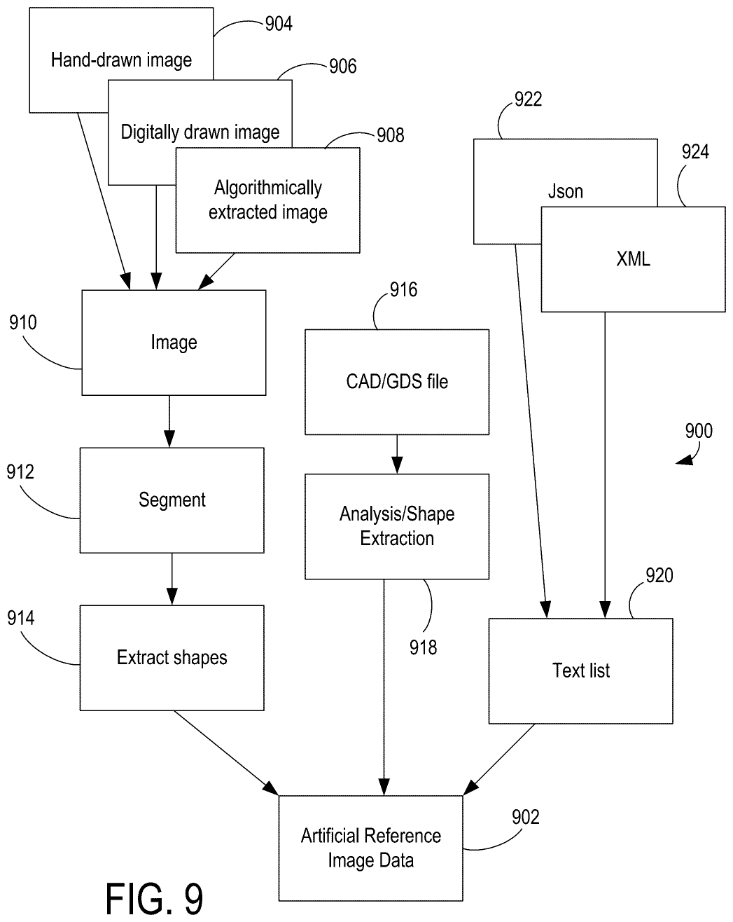

FIG. 9 show various examples 900 of procedures to obtain artificial reference image data 902 that can be used, e.g., in the example method 800 as well as other examples described herein (such as examples 100, 200, 300, 400, 500, 600, 700, etc.). According to some examples, hand drawn images 904, digitally drawn images 906, or algorithmically extracted images 908 may be used as a source image 910. The source image can be segmented at 912 and shapes can be extracted at 914 from the segmented image, e.g., using any of the techniques described herein. In further examples, CAD or GDS files 916 can be used as source data. At 918, the files 916 can be analyzed and shapes extracted. In additional examples, a text-based list 920 can be used, e.g., such as with XML 922, Json 924, or other file formats. The list 920 can be provided in a suitable format so that the artificial reference image data can be compared with found shape data of real images.

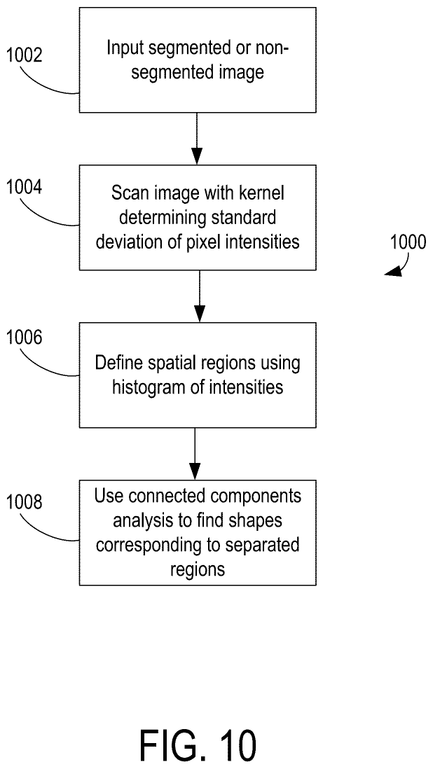

FIG. 10 is an example of a shape-finding method 1000 that can be used to find shapes in images, such as artificial reference images and real images. At 1002, an input image can be provided, such as an already-segmented image with edges detected, or an original or filtered image. At 1004, the image can be scanned analytically with a sliding window of a region of interest, which can be referred to as a kernel in some examples. A standard deviation of the intensities of the pixels in the region of interest of the sliding window can be calculated. The intensities can be sorted with a histogram into a range of intensity peaks. At 1006, spatial regions of the image can be defined as separate regions using the peaks of the histogram. For example, a 1^{st} peak can include all black pixels, a 2^{nd} peak can include grey pixels, and a 3^{rd} peak can include white pixels, which can define different corresponding intensity regions in the image.

At 1008, a connected components analysis (CCA) can be used on the separated intensity regions to find shapes. For example, two separate spaced rectangles can have a similar intensity in the image but be separately spaced through found edges. The other regions that do not correspond to the similar intensity can be converted to black while the two spaced rectangles can be white (or vice versa). From the separated regions, the CCA can search for and find connected components in the image. Each of the connected components can be analyzed to determine if it satisfies some additional parameter requirements that fulfill input conditions, such as shape size, width, height, angle, shape, or other conditions. Another parameter can include a pixel ratio threshold associated with a histogram peak. For example, artifacts can occur (contamination, typos, etc.) in a component that should not otherwise cause the component to be rejected as a found shape candidate. Those connected components that satisfy input conditions can correspond to found shapes.

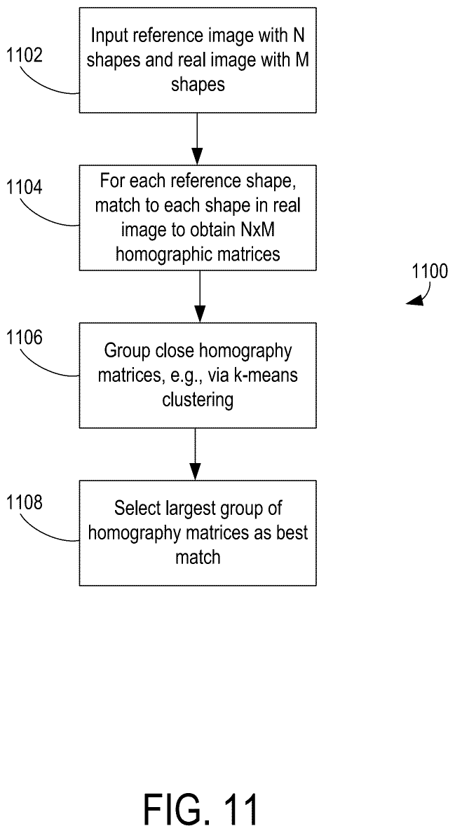

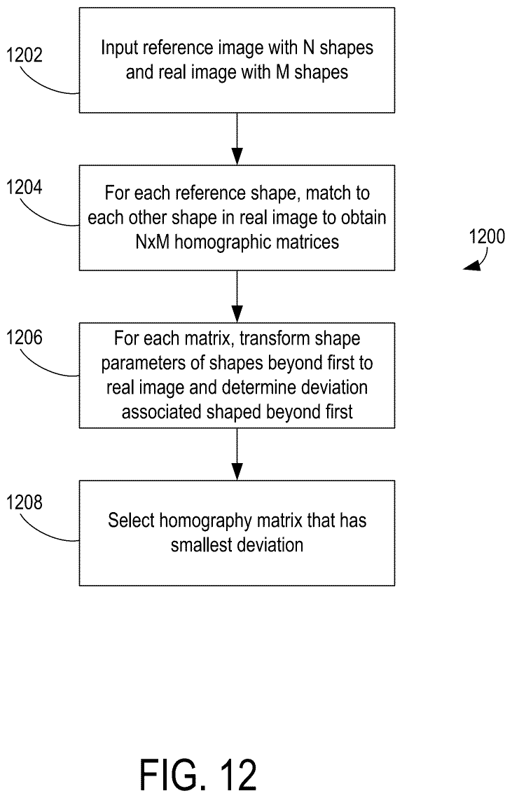

In general, shape matching approaches involve comparing combinations of shapes in a reference image to combinations in a real image. FIG. 11 is an example method 1100 of N-M matching that can be used to find matching shapes between a reference image and a real image. At 1102, a reference image with N found shapes and a real image with M shapes are input for processing. At 1104, each reference shape is compared against each shape in the real image to obtain N×M homography matrices. At 1106, the homography matrices are grouped together based on their similarity, e.g., using k-means clustering. At 1108, the largest group or cluster can be selected as a best match. In some examples, a homography matrix selected for use in mapping and navigation can correspond to an average of the group. FIG. 12 is another example 1200 of N-M matching that can be used to find matching shapes between a reference image and a real image. At 1202, a reference image with N found shapes and a real image with M shapes are input for processing. At 1204, each reference shape is compared against each shape in the real image to obtain N×M homography matrices. At 1206, for each matrix, a deviation is found that is caused by the mapping. For a selected matrix, the principal shape is typically mapped without deviation, but each other shape typically includes a deviation, such as a Euclidean distance, between one or more reference image shape positional points (such as corners) and associated mapped real image shape positional points. At 1208, the homography matrix that has the smallest overall deviation can be selected.

Navigating can be based on virtual maps described herein. In some examples, a reference image can be padded against a real image so that they have a common size.

With the reference image expanded to the field of view of the real image, image segmentation, shape identification, and homography matching can be performed. With the homography matrices obtained, the coordinates of the original region of interest (including specific shapes or positions selected by the user), can be mapped to the coordinates of the real image using the obtained homography matrices. For example, this can provide an overlay of the reference image onto the real image as a virtual map. Then, the homography matrix can be used to transfer the selected reference image location to the location in the real image.

### General Considerations

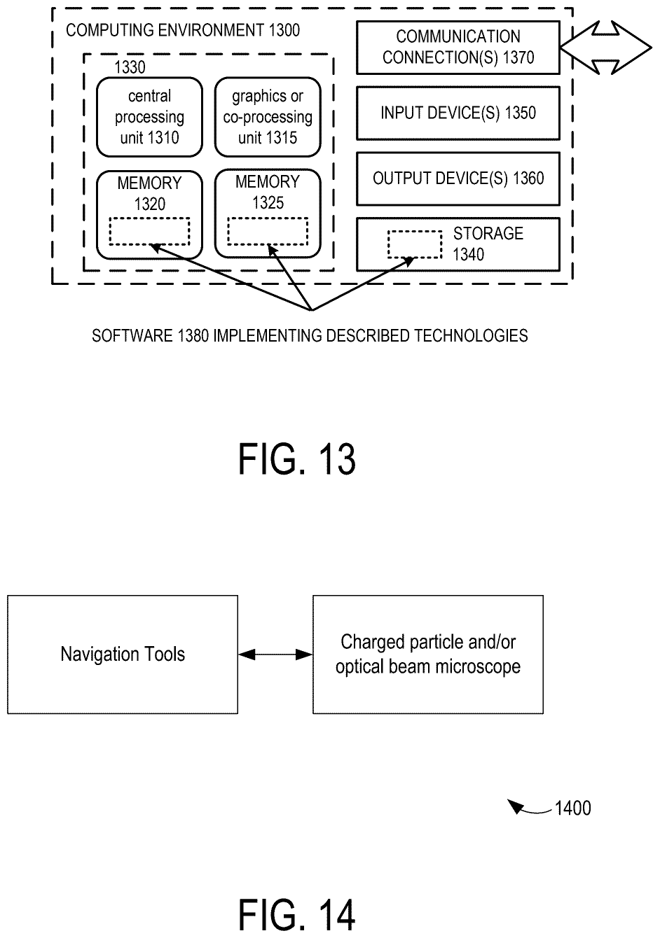

FIG. 13 depicts a generalized example of a suitable computing environment 1300 in which the described innovations may be implemented. The computing environment 1300 is not intended to suggest any limitation as to scope of use or functionality, as the innovations may be implemented in diverse general-purpose or special-purpose computing systems. For example, the computing environment 1300 can be any of a variety of computing devices (e.g., desktop computer, laptop computer, server computer, tablet computer, etc.).

With reference to FIG. 13, the computing environment 1300 includes one or more processing units 1310, 1315 and memory 1320, 1325. In FIG. 13, this basic configuration 1330 is included within a dashed line. The processing units 1310, 1315 execute computer-executable instructions. A processing unit can be a general-purpose central processing unit (CPU), processor in an application-specific integrated circuit (ASIC) or any other type of processor. In a multi-processing system, multiple processing units execute computer-executable instructions to increase processing power. For example, FIG. 13 shows a central processing unit 1310 as well as a graphics processing unit or co-processing unit 1315. The tangible memory 1320, 1325 may be volatile memory (e.g., registers, cache, RAM), non-volatile memory (e.g., ROM, EEPROM, flash memory, etc.), or some combination of the two, accessible by the processing unit(s). The memory 1320, 1325 stores software 1380 implementing one or more methods, portions of methods, combinations of methods, or combinations of portions of methods, described herein, in the form of computer-executable instructions suitable for execution by the processing unit(s). For example, software 1380 can be configured to assemble charged particle beam processing recipes, analyze and compare images and image features, define and/or construct virtual maps, align virtual maps to acquired images, navigate samples based on virtual maps and/or image comparisons, and/or process samples using a charged particle beam microscope.

A computing system may have additional features. For example, the computing environment 1300 includes storage 1340, one or more input devices 1350, one or more output devices 1360, and one or more communication connections 1370. An interconnection mechanism (not shown) such as a bus, controller, or network interconnects the components of the computing environment 1300. Typically, operating system software (not shown) provides an operating environment for other software executing in the computing environment 1300, and coordinates activities of the components of the computing environment 1300.

The tangible storage 1340 may be removable or non-removable, and includes magnetic disks, magnetic tapes or cassettes, CD-ROMs, DVDs, or any other medium which can be used to store information in a non-transitory way and which can be accessed within the computing environment 1300. The storage 1340 stores instructions for the software 1380 implementing one or more innovations described herein.

The input device(s) 1350 may be a touch input device such as a keyboard, mouse, pen, or trackball, a voice input device, a scanning device, or another device that provides input to the computing environment 1300. The output device(s) 1360 may be a display, printer, speaker, CD-writer, or another device that provides output from the computing environment 1300.

The communication connection(s) 1370 enable communication over a communication medium to another computing entity. The communication medium conveys information such as computer-executable instructions, audio or video input or output, or other data in a modulated data signal. A modulated data signal is a signal that has one or more of its characteristics set or changed in such a manner as to encode information in the signal. By way of example, and not limitation, communication media can use an electrical, optical, RF, or other carrier.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed methods can be used in conjunction with other methods.

Any of the disclosed methods can be implemented as computer-executable instructions stored on one or more computer-readable storage media (e.g., one or more optical media discs, volatile memory components (such as DRAM or SRAM), or non-volatile memory components (such as flash memory or hard drives)) and executed on a computer (e.g., any commercially available computer, including smart phones or other mobile devices that include computing hardware). The term computer-readable storage media does not include communication connections, such as signals and carrier waves. Any of the computer-executable instructions for implementing the disclosed techniques as well as any data created and used during implementation of the disclosed embodiments can be stored on one or more computer-readable storage media. The computer-executable instructions can be part of, for example, a dedicated software application or a software application that is accessed or downloaded via a web browser or other software application (such as a remote computing application). Such software can be executed, for example, on a single local computer (e.g., any suitable commercially available computer) or in a network environment (e.g., via the Internet, a wide-area network, a local-area network, a client-server network (such as a cloud computing network), or other such network) using one or more network computers.

For clarity, only certain selected aspects of the software-based implementations are described. Other details that are well known in the art are omitted. For example, it should be understood that the disclosed technology is not limited to any specific computer language or program. For instance, aspects of the disclosed technology can be implemented by software written in C++, Java, Perl, any other suitable programming language. Likewise, the disclosed technology is not limited to any particular computer or type of hardware. Certain details of suitable computers and hardware are well known and need not be set forth in detail in this disclosure.

It should also be well understood that any functionality described herein can be performed, at least in part, by one or more hardware logic components, instead of software. For example, and without limitation, illustrative types of hardware logic components that can be used include Field-programmable Gate Arrays (FPGAs), Program-specific Integrated Circuits (ASICs), Program-specific Standard Products (ASSPs), System-on-a-chip systems (SOCs), Complex Programmable Logic Devices (CPLDs), etc.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, software applications, cable (including fiber optic cable), magnetic communications, electromagnetic communications (including RF, microwave, and infrared communications), electronic communications, or other such communication means.

FIG. 14 shows an example system 1400 that includes a charged particle beam microscope and/or optical microscope configured to process a sample. The system 1400 can be coupled to or include navigation tools for navigating the sample, such as one or more processors configured with instructions to execute any of the methods or portions of the methods described herein.

As used in this application and in the claims, the singular forms “a,” “an,” and “the” include the plural forms unless the context clearly dictates otherwise. Additionally, the term “includes” means “comprises.” Further, the term “coupled” does not exclude the presence of intermediate elements between the coupled items.

The systems, apparatus, and methods described herein should not be construed as limiting in any way. Instead, the present disclosure is directed toward all novel and non-obvious features and aspects of the various disclosed embodiments, alone and in various combinations and sub-combinations with one another. The disclosed systems, methods, and apparatus are not limited to any specific aspect or feature or combinations thereof, nor do the disclosed systems, methods, and apparatus require that any one or more specific advantages be present or problems be solved. Any theories of operation are to facilitate explanation, but the disclosed systems, methods, and apparatus are not limited to such theories of operation.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, methods, and apparatus can be used in conjunction with other systems, methods, and apparatus. Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art.

In some examples, values, procedures, or apparatus'are referred to as “lowest”, “best”, “minimum,” or the like. It will be appreciated that such descriptions are intended to indicate that a selection among many used functional alternatives can be made, and such selections need not be better, smaller, or otherwise preferable to other selections.

In view of the many possible embodiments to which the principles of the disclosed technology may be applied, it should be recognized that the illustrated embodiments are only examples of the disclosed technology and should not be taken as limiting in scope. We therefore claim all that comes within the scope of these claims.

We claim:

1. A computer-implemented method, comprising:
accessing an image of a sample;
detecting one or more shapes in the image;
constructing a virtual map based on the detected one or more shapes in the image and a set of virtual map construction rules; and
based on the virtual map, automatically navigating to a target region of the sample to process the sample with a charged particle beam microscope.

2. The method of claim 1, wherein the accessing the image of the sample comprises, with the charged particle beam microscope, viewing a region of the sample.

3. The method of claim 1, further comprising automatically navigating to a subsequent target region of the sample based on the virtual map to process the sample with the charged particle beam at the subsequent target region.

4. The method of claim 1, wherein the constructing the virtual map comprises accessing embedded virtual map definitions.

5. The method of claim 1, wherein the constructing the virtual map comprises accessing user-defined text-based virtual map generative rules.

6. The method of claim 1, wherein the constructing the virtual map comprises interacting with a graphical user interface to draw shapes depicting one or more structures of interest.

7. The method of claim 1, wherein the constructing the virtual map comprises interacting with a graphical user interface to select and arrange shapes depicting one or more structures of interest.

8. The method of claim 1, further comprising accessing a processing recipe for processing the sample including the target region, wherein the recipe is assembled through selection of map targets from a list of predefined targets.

9. The method of claim 1, further comprising accessing a processing recipe for processing the sample including the target region, wherein the recipe is assembled through selection of map targets from a virtual map representation.

10. The method of claim 1, further comprising accessing a processing recipe for processing the sample including the target region, wherein the recipe is assembled through selection of map targets based on a reference image.

11. The method of claim 10, wherein the selection of map targets based on a reference image comprises a selection of default target positions on the reference image.

12. The method of claim 10, wherein the selection of map targets based on a reference image comprises a selection of user-selected precise positions of interest on the reference image.

13. The method of claim 1, further comprising accessing a processing recipe for processing the sample including the target region, wherein the recipe is assembled by:
selecting a target position in relation to a virtual map arrangement;
determining a shape nearest to the selected target position based on a Euclidean distance; and
storing in the recipe an offset vector between the selected target position and the determined nearest shape;
wherein the automatic navigating to the target region of the sample comprises locating the determined nearest shape in the constructed virtual map and using the stored offset to navigate to the target region.

14. The method of claim 1, wherein the constructing the virtual map based on the detected one or more shapes in the image and a set of virtual map construction rules comprises:
edge detecting the image;
detecting shapes in the edge detection results;
comparing an arrangement of shapes defined by the virtual map construction rules and an arrangement of the detected shapes; and
selecting an alignment of the virtual map with respect to the accessed image having a highest likelihood.

15. The method of claim 1, wherein the constructing the virtual map based on the detected one or more shapes in the image and a set of virtual map construction rules comprises:
accessing edge or shape detections associated with the accessed image and the virtual map construction rules;
constructing point graphs of shapes connected through orientation and adjacency for shape detections and the virtual map defined by the virtual map construction rules;
determining candidate anchors based on a maximum likelihood estimation score of detected shapes wherein candidate solutions are defined as pairings of anchor candidates with corresponding graphs; and
for one or more candidate solutions, comparing its candidate graph with a corresponding virtual map graph to determine a closest match.

16. A charged particle beam microscope configured to process the sample according to the method claim 1.

17. A computer readable medium configured with stored processor-executable instructions for executing the method of claim 1.

18. A computer-implemented method, comprising:
accessing dynamically obtained shape data associated with an image of a sample;
detecting one or more shapes in the image and converting the detected one or more shapes into found shape data;
accessing artificial reference shape data;
comparing the found shape data and the artificial reference shape data with an object matching optimization to determine an alignment between the found shape data and the artificial reference shape data; and
navigating to a target region of the sample to process the sample with a charged particle beam microscope based on the alignment.

19. The method of claim 18, wherein the artificial reference shape data are based on source data comprising any of:
hand-drawn, digitally drawn, or algorithmically extracted images that are segmented with shapes extracted;
CAD and/or GDS files that are analyzed with shapes extracted; and/or
a text-based list.

20. A charged particle beam microscope configured to process the sample according to claim 18.
